(19) United States
(12) Patent Application Publication
(10) Pub. No.: US 2002/0020846 A1
(43) Pub. Date: Feb. 21, 2002

(54) Backside illuminated photodiode array

(76) Inventors: Bo Pi, Carlsbad, CA (US); Timothy C. Collins, Carlsbad, CA (US); Richard L. Conwell, Del Mar, CA (US)

Correspondence Address: JAMES T. HAGLER, Fish & Richardson P.C., 4350 La Jolla Village Drive, Suite 500, San Diego, CA, 92122, US

(21) Appl. No.: 09/838,707

(22) Filed: Apr. 18, 2001

Related U.S. Application Data
(60) Provisional application No. 60/198,914, filed on Apr. 20, 2000.

(51) Int. Cl. H01L 33/00

(52) U.S. Cl. 257/88

(57) ABSTRACT

An improved semiconductor position-sensitive radiation detection device based on a photodiode array formed in a substrate. In one embodiment, the substrate has a first surface and a second surface opposing the first surface. The first surface is electrically conducting to provide a common bias potential to the photodiodes and is optically transparent to receive input photons to be detected. The device includes a grid of conducting wires formed over and in electrical contact with the first surface and configured to define an array of pixels corresponding to the array of photodiodes. A scintillation array of scintillation elements can be coupled to match the pixels defined by the grid of conducting wires and to convert incident radiation at a first wavelength outside the characteristic spectral response range of the substrate into secondary photons at a second wavelength within the spectral response range of the substrate. The scintillation array includes optically reflective surfaces disposed between the scintillation elements to optically isolate one scintillation element from another.

This application claims the benefit of U.S. Provisional Application No. 60/198,914 filed Apr. 20, 2000.

### BACKGROUND

This invention relates to radiation sensing arrays, and more specifically, to backside illuminated photodiode arrays.

A typical photodiode array includes a semiconductor substrate of a first conductivity type, having a front side formed with an array of doped regions of a second, opposite conductivity type, and an opposing back side that includes a heavily-doped bias electrode layer of the first conductivity type. The two types of conductivity in semiconductors are the p-type and n-type. For simplicity, the front side doped regions are referred to below as gates, independent of their function as anodes or cathodes.

In most implementations, an external gate contact, formed from one or conducting layers external to the substrate, is formed over a portion of each of the frontside gates. Similarly, one or more external back contact layers may be formed over all, or a portion of, the backside bias electrode layer. In silicon substrates, the gate contacts are usually formed from one or more metals, metal-silicon intermetallic compounds, or deposited, heavily-doped polysilicon, or a combination of a plurality of these materials. Back contacts to silicon photodiode arrays may use the same materials or a transparent conductor such as indium-tin oxide, referred to below as ITO. In many applications, an array of readout circuits may be formed on the front surface of the substrate. A potential difference, referred to as a reverse bias, can be applied between the gate and the bias electrode layer to produce a depletion region within the substrate extending into the substrate from the p-n junction between the gate on the front side and the substrate. Hence, a photodiode is effected by the gate, the substrate and the bias electrode layer.

Such a photodiode array may be configured either in a front-side illuminated mode to receive photons from the front side or in a backside-illuminated mode to receive photons from the backside. The front-side illuminated mode, however, usually has a lower external quantum efficiency (ratio of photocarriers collected to incident photons) than the backside illuminated mode because the conducting lines of the circuits reduce the active photosensitive area of the array on the front side. In comparison, the entire backside may be used to collect incoming radiation when properly configured. All other factors being equal, enhanced photosensitivity results in increased signal-to-noise ratio. In single-particle radiation detection applications using either direct (intrinsic) detection in the substrate or indirect detection (e.g., using scintillators as discussed below) enhanced photosensitivity results in improved particle energy resolution. In addition, the conducting lines and other physical features such as steps in dielectric thicknesses can scatter light into the photosensitive areas of adjacent photodiodes, thereby reducing image contrast. Contrast degradation modifies the modulation transfer function of the array and can reduce the useful spatial resolution of the array. Therefore, backside illuminated photodiode arrays are frequently used in imaging applications to improve photosensitivity, signal-to-noise ratio, particle energy resolution spatial resolution.

In a back-illuminated photodiode, photocurrent is typically generated by band-to-band absorption. Photons with energy greater than the bandgap of the semiconductor enter the back of the substrate and are absorbed, producing electron-hole pairs. If an electron-hole pair is generated outside the depletion region, the minority carrier (a hole in the example above) diffuses to the edge of the depletion region beneath one of the gates. The electric field within the depletion region “collects” the hole by accelerating it towards the gate. If, however, a photon is absorbed within the depletion region of a gate, the electric field “collects” the hole as above, but accelerates the electron towards the undepleted substrate. In either case, the photocurrent will flow through the photodiode and the external circuitry that maintains the bias between the gate and the back contact. If readout circuitry is provided on same semiconductor substrate, the circuit elements associated with each gate will produce a signal that represents a function of the photocurrent, the quantity of charge caused by the photon absorption, or a combination of both.

In a typical backside illuminated photodiode array, a transparent conductive anti-reflection (AR) coating such as indium tin oxide (ITO) is formed over a heavily-doped layer which constitutes the back contact. See, e.g., U.S. Pat. No. 6,025,585 to Holland; Holland et al., “Development of low noise, backside illuminated silicon photodiode arrays,” IEEE Transactions on Nuclear Science, Vol. 44, No. 3, June, 1997, and Kwa et al., “Backside-illuminated silicon photodiode array for an integrated spectrometer,” IEEE Transactions on Electron Devices, Vol. 44, No. 5, May, 1997.

### SUMMARY

The present disclosure includes a position-sensitive radiation detection device based on a backside illuminated photodiode array formed in a substrate. The substrate may be formed of a semiconductor material having first and second surfaces opposing each other and including suitable dopants to exhibit a first conductivity type. A transparent conducting layer of the first conductivity type is formed over the first surface to distribute a common potential on the transparent conducting layer. An array of doped gate regions of a second conductivity type is formed on the second surface to effectuate an array of photodiodes.

The position-sensitive radiation detection device may include a pattern of highly conducting material (grid) formed on the back of the device, in electrical contact with the bias electrode layer or back contact (if provided), and configured to define an array of pixels corresponding to the array of gates on the second surface. The highly conductive material may be fabricated under or over the anti-reflection coating on the first surface. A circuit layer formed over the second surface provides a gate contact to each doped region and may include a readout circuit for each photodiode.

The photodiode array may be operated by illuminating the first surface of the substrate through the openings in the conductive grid. Advantages of this position-sensitive radiation detection device include improved uniformity of the bias voltage applied to different photodiode, reduced resistance of each photodiode, and an associated reduction in noise. The use of the grid on the first surface increases the immunity of the device to external disturbances (interference).

An anti-reflection layer may be formed over the transparent conducting layer over the bias electrode layer within each pixel to reduce reflection of photons incident on the first surface. Since the grid of is used to provide and distribute the common bias potential to the pixels, the AR layer can be electrically insulating and configured independent of the electrical consideration of the device. Therefore, a dielectric layer may be selected from a wide range of dielectric materials in a relation to the refractive index of the first surface to achieve optimal anti-reflection. Use of insulating AR coatings may also provide a greater range of materials that can be patterned chemically when needed.

A transparent conducting layer can be completely eliminated if the bias electrode layer has sufficient conductivity and an indirect back surface contact is provided. The indirect back surface contact is also compatible with the use of insulating AR coating materials.

The position-sensitive radiation detection device may also include an array of scintillation elements to convert radiation at a first wavelength outside the spectral response range of the substrate into secondary photons at a second wavelength within the spectral response range of the substrate. In one implementation, the scintillation elements can be formed in a scintillation crystal and coupled to the grid. The scintillation elements can therefore be accurately aligned with the photodiodes defined by the grid and can be optically isolated from one another by providing optically reflective surfaces disposed between the scintillation elements. Such structures can significantly reduce or eliminate cross talk between adjacent pixels.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIGS. 1 and 2 schematically show a backside illuminated photodiode array in accordance with one embodiment of the invention.

FIG. 3 schematically shows the photodiode array of FIG. 1 with a scintillation crystal array coupled to the grid of conducting wires formed on the back side of the photodiode array.

Like reference numbers and designations in the various drawings indicate like elements.

### DETAILED DESCRIPTION

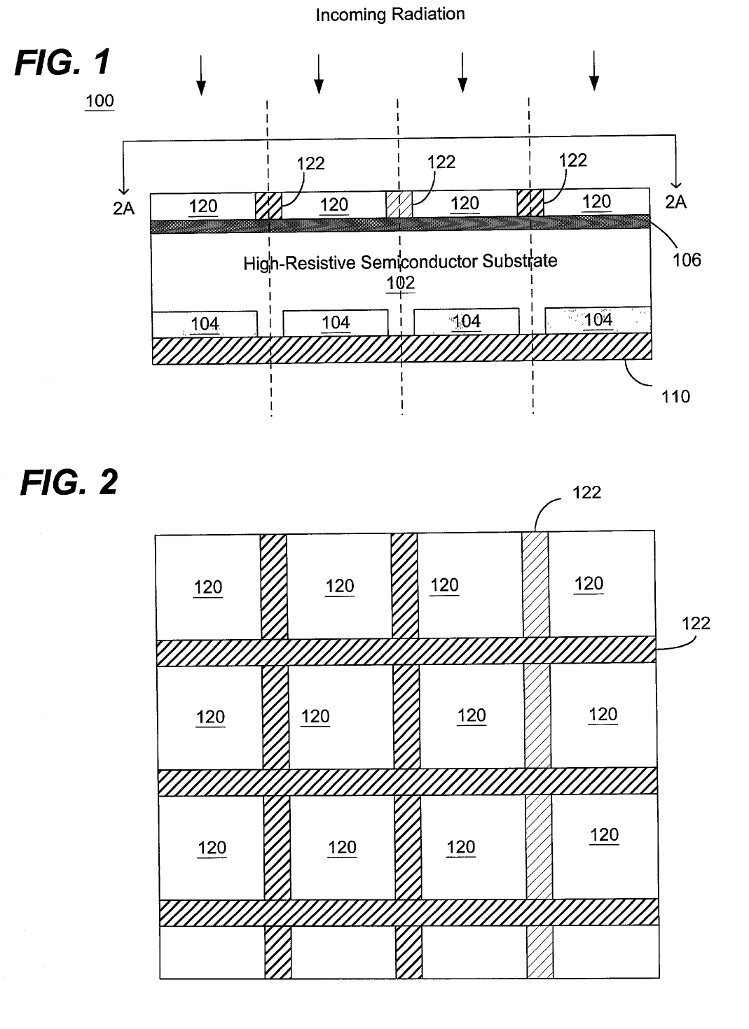

FIG. 1 shows an improved backside illuminated photodiode array 100 according to one embodiment of the invention. A semiconductor substrate 102 may be lightly doped to exhibit the n-type conductivity (or alternatively, the p-type conductivity) and have a high resistivity. For example, silicon may be used to form the substrate 102 with a resistivity on the order of about 10 kΩ˜cm. One side of the substrate 102, the front side, is selectively doped at different locations to form an array of heavily p-doped gate regions 104 that are separated from one another. A p-n junction is formed by each region 102 and the surrounding n-region of the substrate 102 and functions as a photosensitive element (i.e., a photodiode) to detect photons within a spectral range. A circuit layer 110 is next formed over the front side of the substrate 102 and provides gate contacts and readout circuits to the photodiodes. The opposing side of the substrate 102, i.e., the backside, is configured to form a transparent conducting layer 106. This layer 106 may be internal to the substrate 102 by heavily doping the backside with the same type conductivity as the substrate, e.g., n-type dopants in the present example, to form a conducting crystalline bias electrode layer. Alternatively, this layer 106 may be external to the substrate 102 by engaging an external back contact layer to the outer surface on the backside of the substrate 102, e.g., a polycrystalline silicon back contact layer. For brevity, the acronym BEL is used below to denote a conducting bias electrode layer internal to the substrate. In principle, a transparent conducting back contact layer external to the substrate can be used in place of, or in conjunction with, the conducting bias electrode layer as described. Any such transparent conducting layer external to the substrate (and to the polysilicon back contact, if employed) should be used with caution. The presence of the transparent conducting layer should not increase the generation of minority carriers (holes in this example), because the generated holes can increase the leakage current of the photodiodes, thereby degrading the signal-to-noise ratio and particle energy resolution. A transparent conducting layer can be completely eliminated if the bias electrode layer has sufficient conductivity and an indirect back surface contact is provided. This technique is described in U.S. patent application 09/607,547 filed on Jun. 29, 2000 by Carlson, the entirety of which is incorporated herein by reference. The indirect back surface contact is compatible with the use of insulating AR coating materials.

The bias electrode layer or external back contact layer 106 is electrically biased to a different potential from the 104 so that a depletion region is formed near each p-n junction. The internal electric field within the depletion region collects photo-generated holes. The readout circuit (if provided) associated with each photodiode gate then detects the photon-induced charge and/or and produces a corresponding output signal.

The photodiode array 100 in FIG. 1 is configured in the backside-illuminated mode to receive incoming photons from the backside having the conducting BEL 106. A grid of conducting wires 122, made of aluminum or other suitable conducting materials, is formed over the polysilicon layer 106 and divides the backside of the substrate 102 into a plurality of pixels enclosed by the conducting wires 122. Each pixel of the grid is positioned and dimensioned to correspond to a respective p-doped region 104 on the front side of the substrate 102. Hence, the grid of conducting wires 122 physically defines the boundaries of each photodiode as indicated by the dashed lines in FIG. 1. FIG. 2 is a side view of the front side of the substrate 102 along the line 2A-2A.

An anti-reflection layer 120 is formed over the BEL 106 within each pixel. The anti-reflection layer 120 may be formed of any suitable materials such as a conducting layer of ITO or a non-conducting dielectric multi-layer stack. In many implementations, the anti-reflection layer 120 may be preferably formed by a dielectric multi-layer stack optimally matched to the refractive index of the BEL 106 according to well-know optical design procedures. Hence, the anti-reflection layer 120 can be configured independently from issues affecting the electrical performance of the backside and can be selected from a wide range of dielectric materials to achieve the optimal optical performance. Use of a such dielectric stack allows achievement of a high photon-collection efficiency, usually difficult to achieve using limited number of conducting anti-reflection materials.

The grid of conducting wires 122 provides several functions and benefits in addition to defining pixels for the photodiode array 100. The conducting wires 122 are connected to a voltage source to distribute a bias electrical potential on the conducting bias electrode layer or external back contact layer 106. Since the conducting wires 122 are distributed over the entire BEL or external back contact 106 and enclose each pixel, this configuration enhances the uniformity of the bias voltages applied to the individual photodiodes, thereby improving the uniformity in the photo responses of photodiodes if all other conditions are equal.

The grid of conducting wires 122 provides a low-resistance path from the power source to each photodiode. Since the internal noise generated at each photodiode and the disturbances (interference)received by each photodiode are approximately proportional to the resistance associated with each photodiode, the use of the grid of the conducting wires 122 reduces the noise and improves the immunity to external interference.

The anti-reflection layer 120 and conducting wires 122 may be substantially coplanar with each other. Known semiconductor processing techniques may be used. In particular, the conducting wires 122 may be formed by using a metalization process to reduce the fabrication cost and improve device reliability.

Many imaging applications require detection of radiation in a spectral range that is out of the characteristic spectral response range of the semiconductor substrate. Conventionally, a scintillation crystal array is interposed between the source of radiation and the photodiode array to covert the incident radiation into secondary radiation in a spectral range detectable by the photodiode array. Each element of the scintillation crystal array is co-aligned with a photodiode of the photodiode array. Even if the incident particle is completely absorbed in a single scintillator crystal, secondary photons emitted at an angle from the output window of the scintillator may be collected by an adjoining photodiode, thereby producing crosstalk between adjacent photodiodes Such crosstalks degrades the modulation transfer function and useful spatial resolution of the photodiode array as discussed above.

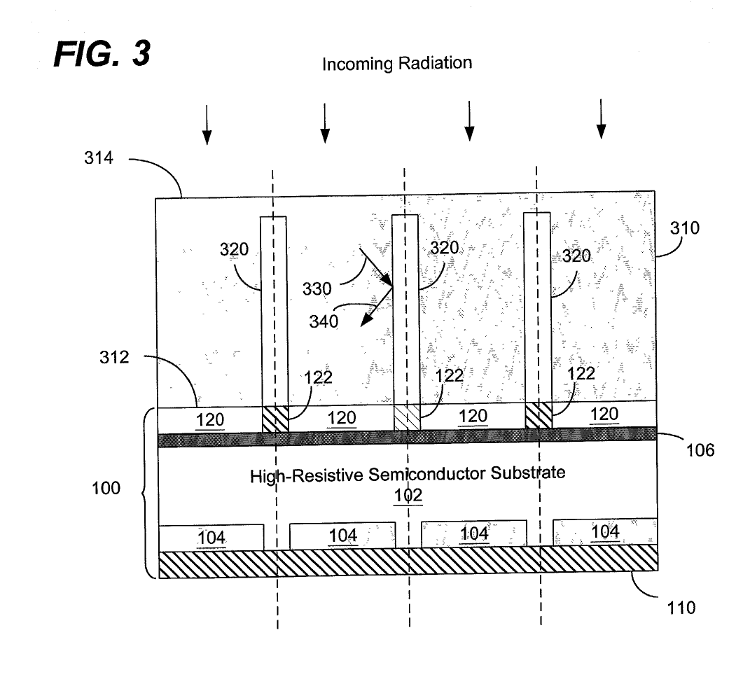

The photodiode array 100 of FIG. 1 can be used to couple an array of scintillators to the front side of the substrate 102 to reduce or eliminate the above crosstalk effect. FIG. 3 shows one example of the photodiode array coupled to a scintillator crystal 310. The scintillator crystal 310 is processed to have trenches 320 that partition the crystal 310 into scintillation pixels corresponding to the pixels defined by the grid of conducting wires 122 on the backside of the substrate 102. The trenches 320 cut through one side 312 of the crystal 310 but not the opposing side 314. The pattern of trenches on side 312 is matched to the pattern of the grid of conducting wires 122. When the crystal 310 is placed over, or engaged to, the backside of the substrate 102, the trenches 320 in the scintillation pixels of the crystal 310 are aligned precisely over the pattern of the conducting wires 122. The pixels in the scintillator crystal array therefore are precisely aligned with the pixels of the photodiode array 100.

Each trench 320 may be filled with a reflective material so that different pixels are optically isolated. For example, the trench 320 reflects a slanted ray 330 in one scintillation pixel as a reflected ray 340 to prevent it from entering an adjacent photodiode.

Although only a preferred embodiment of the present invention has been described, various modifications may be made without departing from the spirit and scope of the invention. As stated above, all statements and claims herein are equally true if the conductivity types of all the layers are reversed and the corresponding changes are made to the polarities of the charge carriers, applied voltages and electric fields. As yet another example, the filled reflective material in the trench 320 in FIG. 3 may be replaced by reflective coating on the sidewalls. Accordingly, other embodiments are within the scope of the following claims.

What is claimed is:

1. A semiconductor position-sensitive radiation detection device, comprising:
a substrate formed of a semiconductor material doped to exhibit a first conductivity type and configured to have first and second surfaces opposing each other, the substrate having (1) a transparent conducting bias electrode layer formed over the first surface and in electrical contact thereto and (2) an array of doped gate regions of a second conductivity type on the second surface; and
a grid of conducting wires formed over and in electrical contact with the conducting bias electrode layer or back contact layer on the first surface and configured to define an array of pixels corresponding to the array of doped regions;
wherein the grid of conducting wires is connected to distribute a common potential on the transparent conducting bias electrode layer so as to bias the substrate with respect to the doped regions to effect a photodiode array that receives radiation from the first surface.

2. The device as in claim 1, wherein the transparent conducting bias electrode layer is internal to the substrate and is formed by doping a layer of the substrate near the first surface to exhibit the first conductivity type.

3. The device as in claim 1, wherein the transparent conducting bias electrode layer is external to the substrate and is formed from a transparent conductor layer externally attached to the first surface.

4. The device as in claim 3, wherein the transparent back contact layer includes a heavily-doped polycrystalline layer of a semiconductor material that forms the substrate.

5. The device as in claim 1, wherein the transparent conducting bias electrode layer includes a first layer external to the substrate and formed from a transparent conductor layer externally attached to the first surface and a second layer internal to the substrate and formed by doping a layer of the substrate near the first surface to exhibit the first conductivity type.

6. The device as in claim 1, further comprising a circuit layer formed over the second surface to provide a gate contact to and a readout circuit for each doped region,

7. The device as in claim 1, further comprising a scintillation array of scintillation elements formed in a scintillator crystal operable to convert incident radiation at a spectral range outside the characteristic spectral response range of the substrate into secondary photons at a second wavelength within the spectral response range of the substrate, said scintillation array being coupled to the grid of conducting wires on the first surface of the substrate, wherein the scintillation elements match the size of and are aligned with the photodiodes of the photodiode array defined by the grid of conducting wires and the scintillation array includes optically reflective surfaces disposed between the scintillation elements to optically isolate one scintillation element from another.

8. The device as in claim 7, wherein one of the first and second conductivity types is caused by n-type dopants and the other is caused by p-type dopants.

9. The device as in claim 7, wherein the substrate includes silicon.

10. The device as in claim 7, wherein the transparent conducting bias electrode layer is internal to the substrate and includes a heavily-doped crystalline layer.

11. The device as in claim 7, wherein the grid of conducting wires is formed of a metallic material.

12. The device as in claim 11, wherein the metallic material includes aluminum.

13. The device as in claim 7, further comprising an anti-reflection layer formed over the transparent conducting layer within each pixel and configured to reduce reflection of photons incident on the first surface.

14. The device as in claim 13, wherein the anti-reflection layer is electrically insulating.

15. The device as in claim 13, wherein the anti-reflection layer includes a dielectric layer having a refractive index that has a relation with a refractive index of the transparent conducting layer.

16. The device as in claim 1, wherein one of the first and second conductivity types is caused by n-type dopants and the other is caused by p-type dopants.

17. The device as in claim 1, wherein the substrate includes silicon.

18. The device as in claim 7, further comprising an anti-reflection layer formed over the transparent conducting layer within each pixel and configured to reduce reflection of photons incident on the first surface.

19. A semiconductor position-sensitive radiation detection device, comprising:
array of photodiodes formed in a substrate having a first surface and a second surface opposing the first surface, wherein the first surface is electrically conducting to provide a common bias potential to the photodiodes and is optically transparent to receive input photons to be detected; and
grid of conducting wires formed over and in electrical contact with the first surface and configured to define an array of pixels corresponding to the array of photodiodes, wherein the grid of conducting wires is connected to distribute a common potential to the photodiodes.

20. The device as in claim 19, further comprising a scintillation array of scintillation elements formed in a scintillator crystal operable to convert incident radiation at a first wavelength outside the characteristic spectral response range of the photodiodes into secondary photons at a second wavelength within the spectral response range of the substrate and coupled to the grid of conducting wires on the first surface of the substrate, wherein the scintillation elements match, and are aligned with, the pixels defined by the grid of conducting wires and the scintillation array includes optically reflective surfaces disposed between the scintillation elements to optically isolate one scintillation element from another.

21. The device as in claim 20, further incorporating an anti-reflection layer formed over the first surface within each pixel and configured to reduce reflection of photons incident to the first surface.

22. The device as in claim 21, wherein the anti-reflection layer is electrically insulating.

23. The device as in claim 21, wherein the anti-reflection layer includes a dielectric layer having a refractive index that has a relation with a refractive index of the first surface.

24. The device as in claim 19, further incorporating an anti-reflection layer formed over the first surface within each pixel and configured to reduce reflection of photons incident to the first surface.

25. The device as in claim 19, further comprising a circuit layer formed over the second surface to provide a gate contact to and, if provided, a readout circuit for each photodiode,

26. The device as in claim 19, wherein the conductivity of the first surface is formed by doping a layer of the substrate near the first surface to exhibit the same conductivity as the substrate.

27. The device as in claim 19, wherein the conductivity of the first surface the transparent is formed from a transparent conductor layer externally attached to the first surface.

28. The device as in claim 27, wherein the transparent conductor layer includes a heavily-doped polycrystalline layer of a semiconductor material that forms the substrate.
